(19) United States
(12) Patent Application Publication
(10) Pub. No.: US 2025/0226285 A1
(43) Pub. Date: Jul. 10, 2025

(54) SEMICONDUCTOR PACKAGE

(71) Applicant: Samsung Electronics Co., Ltd., Suwon-si (KR)

(72) Inventors: Myungsung Kang, Suwon-si (KR); Jinwoo Park, Suwon-si (KR); Kyonghwan Koh, Suwon-si (KR); Hyeonjun Jin, Suwon-si (KR)

(21) Appl. No.: 18/794,266

(22) Filed: Aug. 5, 2024

(30) Foreign Application Priority Data
Jan. 9, 2024 (KR) 10-2024-0003396

(51) Int. Cl. H01L 23/373; H01L 23/00; H01L 23/31; H01L 23/498; H01L 23/538; H01L 25/10

(52) U.S. Cl. CPC H01L 23/3736; H01L 23/49822; H01L 24/24; H01L 25/105; H01L 23/3107; H01L 23/49811; H01L 23/5383; H01L 24/16; H01L 24/32; H01L 24/33; H01L 24/48; H01L 24/73; H01L 2224/16227; H01L 2224/24146; H01L 2224/32225; H01L 2224/33181; H01L 2224/48227; H01L 2224/73204; H01L 2224/73265; H01L 2225/1094

(57) ABSTRACT

A semiconductor package includes a front redistribution structure, a semiconductor chip, external connection bumps, an encapsulant, a rear redistribution structure, an interconnection structure, an upper package that is on the rear redistribution structure, and a heat dissipation structure that includes a bonding layer that is on at least one side of the upper package and on the rear redistribution structure, where the heat dissipation structure includes a dam structure that at least partially surrounds at least a portion of the bonding layer in plan view and is on the rear redistribution structure, and where the heat dissipation structure includes a heat slug on the bonding layer.

### CROSS-REFERENCE TO RELATED APPLICATION(S)

This application claims benefit of priority to Korean Patent Application No. 10-2024-0003396 filed on Jan. 9, 2024 in the Korean Intellectual Property Office, the disclosure of which is incorporated herein by reference in its entirety.

### TECHNICAL FIELD

The present disclosure relates to a semiconductor package.

### BACKGROUND

With a reduction in weight and an implementation of high performance of electronic devices, the development of semiconductor packages, having a reduced size and high performance, has been desired in the field of semiconductor packages. To improve the reliability of high-performance semiconductor chips, the heat dissipation properties of semiconductor packages have become increasingly evaluated.

### SUMMARY

An aspect of the present disclosure provides a semiconductor package having improved reliability.

According to an aspect of the present disclosure, there is provided a semiconductor package including a front redistribution structure that includes a front insulating layer and front redistribution layers in the front insulating layer, a semiconductor chip on a first surface of the front redistribution structure, external connection bumps on a second surface of the front redistribution structure, where the external connection bumps are electrically connected to ones of the front redistribution layers, an encapsulant on a portion of the semiconductor chip and on the first surface of the front redistribution structure, a rear redistribution structure that includes a rear insulating layer on the encapsulant, rear redistribution layers in the rear insulating layer, and rear pads on the rear insulating layer, an interconnection structure that extends into the encapsulant and electrically connects the front redistribution layers and the rear redistribution layers to each other, an upper package that is on the rear redistribution structure and is electrically connected to the rear pads of the rear redistribution structure, and a heat dissipation structure that includes a bonding layer that is on at least one side of the upper package and on the rear redistribution structure, where the heat dissipation structure includes a dam structure that at least partially surrounds at least a portion of the bonding layer in plan view and is on the rear redistribution structure, and where the heat dissipation structure includes a heat slug on the bonding layer.

According to another aspect of the present disclosure, there is provided a semiconductor package including a lower package and a heat dissipation structure. The lower package includes: a front redistribution structure that includes front redistribution layers, a semiconductor chip on the front redistribution structure, an encapsulant that is on a portion of the semiconductor chip and on the front redistribution structure, and a rear redistribution structure that includes a rear insulating layer on the encapsulant, rear redistribution layers in the rear insulating layer, and rear pads on the rear insulating layer. The heat dissipation structure includes: a dam structure that is spaced apart from the rear pads in a first direction that is parallel to an upper surface of the lower package and is on the rear insulating layer, the dam structure defining a through-hole that exposes a first portion of an upper surface of the rear insulating layer, a bonding layer that is in at least a portion of the through-hole and is on at least a portion of an upper surface of the dam structure, and a heat slug on the bonding layer.

According to another aspect of the present disclosure, there is provided a semiconductor package including a lower package and an upper package. The lower package includes: a front redistribution structure that includes a front insulating layer and front redistribution layers in the front insulating layer, a semiconductor chip that is on the front redistribution structure and electrically connected to the front redistribution layers, an encapsulant that is on at least a portion of the semiconductor chip and is on the front redistribution structure, and a rear redistribution structure that includes a rear insulating layer on the encapsulant, rear redistribution layers in the rear insulating layer, and rear pads on the rear insulating layer. The upper package includes: an upper package substrate, an upper semiconductor chip on the upper package substrate, an upper encapsulant on at least a portion of the upper semiconductor chip, and connection conductors that are electrically connected to the rear pads, where the semiconductor package includes a heat dissipation structure that includes a bonding layer that is spaced apart from the upper package in a first direction that is parallel to an upper surface of the lower package and is on the rear redistribution structure, a dam structure that at least partially surrounds a portion of the bonding layer in plan view and is on the rear redistribution structure, and a heat slug on the bonding layer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1A is a cross-sectional view of a semiconductor package according to example embodiments;

FIG. 1B is a plan view of a semiconductor package according to example embodiments;

FIG. 1C is a cross-sectional view of a semiconductor package according to example embodiments;

FIG. 1D is an enlarged view of region “A” of FIG. 1A;

FIGS. 2, 3, 4, and 5 are enlarged views of modifications of region “A” of FIG. 1A;

FIGS. 6 and 7 are cross-sectional views of semiconductor packages according to example embodiments;

FIG. 8 is a cross-sectional view of a semiconductor package according to example embodiments; and

FIGS. 9A, 9B, 9C, 9D, 9E, 9F, 9G, 9H, 9I, and 9J are diagrams of sequential processes of a method of manufacturing a semiconductor package according to example embodiments.

### DETAILED DESCRIPTION

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device.

Hereinafter, example embodiments of the present disclosure will be described with reference to the accompanying drawings. Terms such as “top,” “upper portion,” “upper surface,” “above,” “bottom,” “lower portion,” “lower surface,” “below,” and “side surface” may be understood as being referred to based on the drawings except for being denoted by reference numerals.

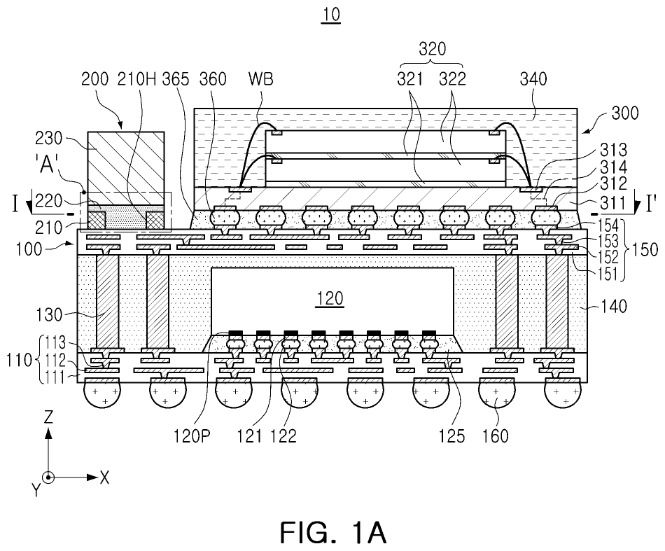

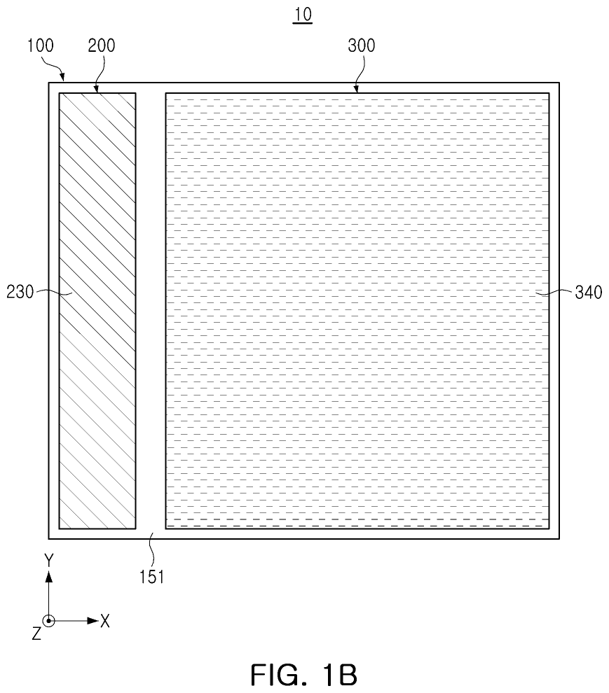

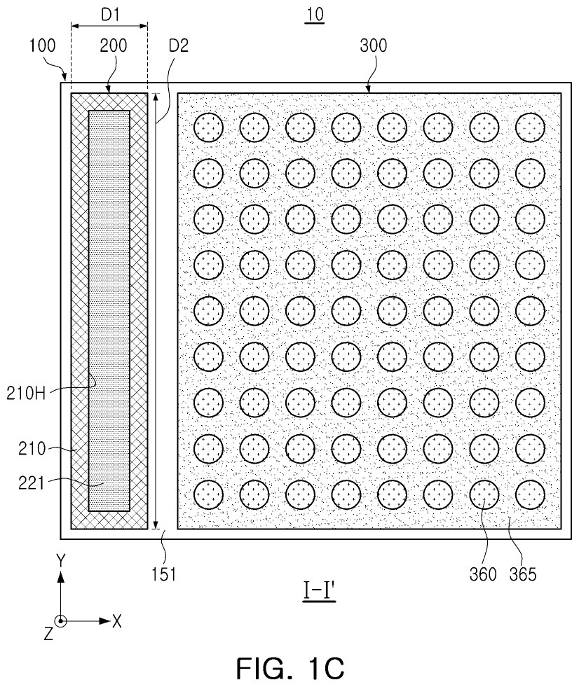

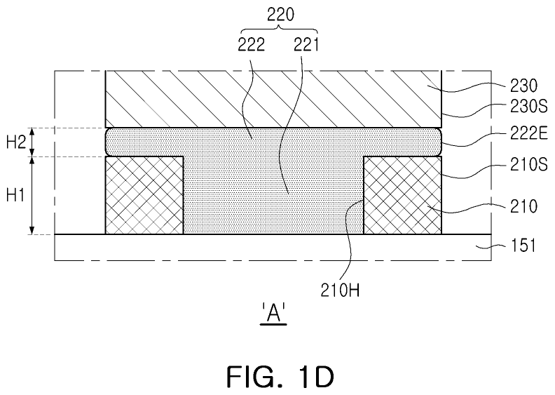

FIG. 1A is a cross-sectional view of a semiconductor package 10 according to example embodiments. FIG. 1B is a plan view of a semiconductor package 10 according to example embodiments. FIG. 1B is a plan view of the semiconductor package 10 according to example embodiments of FIG. 1A, and only some components are illustrated for ease of description. FIG. 1C schematically illustrates a cross-section taken along line I-I′ of FIG. 1A. FIG. 1D is an enlarged view of region “A” of the semiconductor package 10 according to example embodiments of FIG. 1A.

Referring to FIGS. 1A to 1D, the semiconductor package 10 according to an example embodiment may include a lower package 100, a heat dissipation structure 200, and an upper package 300. The lower package 100 may include a front redistribution structure 110, a semiconductor chip 120, an interconnection structure 130, an encapsulant 140, a rear redistribution structure 150, and external connection bumps 160. The heat dissipation structure 200 may include a dam structure 210, a bonding layer 220, and a heat slug 230. The upper package 300 may include an upper package substrate 311, a second semiconductor chip 320, an upper encapsulant 340, connection conductors 360, and an upper underfill layer 365. The lower package 100 may be referred to as a lower semiconductor package 100 or a first semiconductor package 100, and the upper package 300, disposed on the lower package 100, may be referred to as an upper semiconductor package 300 or a second semiconductor package 300.

The front redistribution structure 110 may include a front insulating layer 111, front redistribution layers 112, and front redistribution vias 113. The front redistribution structure 110 may be a support substrate on which the semiconductor chip 120 is mounted.

The front insulating layer 111 may include an insulating resin. The insulating resin may include a thermosetting resin such as an epoxy resin, a thermoplastic resin such as polyimide, or a resin in which the above-described resins are impregnated with an inorganic filler, for example, a prepreg, an ABF, FR-4, or BT. For example, the front insulating layer 111 may include a photosensitive resin such as a photoimageable dielectric (PID). The front insulating layer 111 may include a plurality of insulating layers (not illustrated) stacked in a vertical direction (Z-axis direction). Depending on the process, the plurality of insulating layers (not illustrated) may have unclear or may lack boundaries therebetween.

The front redistribution layers 112 may be disposed on or in the front insulating layer 111, and may redistribute a connection terminal 120P of the semiconductor chip 120. The front redistribution layers 112 may include, for example, a metal including copper (Cu), aluminum (Al), silver (Ag), tin (Sn), gold (Au), nickel (Ni), lead (Pb), titanium (Ti), or alloys thereof. The front redistribution layers 112 may perform various functions depending on the design. For example, the front redistribution layers 112 may include a ground (GND) pattern, a power (PWR) pattern, and a signal(S) pattern. Here, the signal(S) pattern may be defined as a transmission path for various signals, such as a data signal and the like, excluding the ground (GND) pattern, the power (PWR) pattern, and the like. The front redistribution layers 112 may include more or fewer redistribution layers than those illustrated in the drawings. The front redistribution layers 112, which are disposed on the front insulating layer 111, may be electrically connected to a plurality of interconnection structures 130 and the connection terminals 120P of the semiconductor chip 120.

The front redistribution vias 113 may extend vertically in the front insulating layer 111 to be electrically connected to the front redistribution layer 112. For example, the front redistribution via 113 may interconnect front redistribution layers 112 on different levels. The front redistribution vias 113 may include a signal via, a ground via, and a power via. The front redistribution vias 113 may include, for example, a metal material including copper (Cu), aluminum (Al), silver (Ag), tin (Sn), gold (Au), nickel (Ni), lead (Pb), titanium (Ti), or alloys thereof. The front redistribution vias 113 may be a filled via in which a via hole is filled with or includes a metal material or a conformal via in which a metal material extends along an inner wall of a via hole.

The semiconductor chip 120 may include a connection terminal 120P disposed on the front redistribution structure 110 and electrically connected to the front redistribution layers 112. The semiconductor chip 120 may be referred to as a lower semiconductor chip 120 or a first semiconductor chip 120. The semiconductor chip 120 may include a semiconductor wafer and a semiconductor wafer integrated circuit (IC), including a semiconductor element such as silicon or germanium, or a compound semiconductor such as silicon carbide (SiC), gallium arsenide (GaAs), indium arsenide (InAs), and indium phosphide (InP). The semiconductor chip 120 may be a bare semiconductor chip without a bump or interconnection line layer, but the present disclosure is not limited thereto. The semiconductor chip 120 may be a packaged-type semiconductor chip. An integrated circuit may be a logic circuit (or “logic chip”), such as a central processing unit (CPU), a graphics processing unit (GPU), a field programmable gate array (FPGA), an application processor (AP), a digital signal processor, a cryptographic processor, a microprocessor, a microcontroller, an analog-to-digital converter, or an application-specific integrated circuit (ASIC), or a memory circuit (or “memory chip”) including a volatile memory such as a dynamic RAM (DRAM) or a static RAM (SRAM), and a non-volatile memory such as a phase change RAM (PRAM), a magnetic RAM (MRAM), a resistive RAM (RRAM), or a flash memory.

The semiconductor chip 120 may include a connection pillar 121 and a connection solder 122 that connects a connection terminal 120P to the front redistribution layer 112 on the front insulating layer 111. The connection pillar 121 and the connection solder 122 may be disposed between the front redistribution layer 112 on the front insulating layer 111 and the connection terminal 120P. An underfill layer 125 may be disposed between the semiconductor chip 120 and the front redistribution structure 110. The underfill layer 125 may include an insulating resin such as an epoxy resin, and may physically and electrically protect the connection pillar 121 and the connection solder 122. The underfill layer 125 may have a capillary underfill (CUF) structure, but the present disclosure is not limited thereto. In some example embodiments, the underfill layer 125 may have a moled underfill (MUF) structure integrated with the encapsulant 140.

The interconnection structure 130 may pass through or extend into the encapsulant 140 to electrically connect the front redistribution layers 112 and the rear redistribution layers 152 to each other. The interconnection structure 130 may extend in the vertical direction (Z-direction) in the encapsulant 140. An upper surface of the interconnection structure 130 may be exposed from or by the encapsulant 140, and may be substantially coplanar with an upper surface of the encapsulant 140. For example, the interconnection structure 130 may have a post shape, passing through or extending into the encapsulant 140. However, the shape of the interconnection structure 130 is not limited thereto. The interconnection structure 130 may include a metal material such as copper (Cu). In some example embodiments, a metal seed layer (not illustrated), including titanium (Ti), copper (Cu), or the like, may be formed on a lower surface of the interconnection structure 130.

The encapsulant 140 may encapsulate at least a portion of the semiconductor chip 120, and is on an upper surface of the front redistribution structure 110. The encapsulant 140 may cover or at least partially overlap a side surface and an upper surface of the semiconductor chip 120. The encapsulant 140 may include, for example, a thermosetting resin such as an epoxy resin, a thermoplastic resin such as polyimide, or a resin in which the above-described resins are impregnated with an inorganic filler, for example, a prepreg, an ABF, FR-4, BT, or an epoxy molding compound (EMC). For example, the encapsulant 140 may include the EMC.

The rear redistribution structure 150 may be disposed on the semiconductor chip 120 and the encapsulant 140, and may include a rear insulating layer 151, rear redistribution layers 152, rear redistribution vias 153, and rear pads 154.

The rear insulating layer 151 may include an insulating resin. The insulating resin may include a thermosetting resin such as an epoxy resin, a thermoplastic resin such as polyimide, or a resin in which the above-described resins are impregnated with an inorganic filler, for example, a prepreg, an ABF, FR-4, BT, or a PID. The rear insulating layer 151 may include a plurality of layers stacked in the vertical direction (Z-axis direction). Depending on the process, the plurality of layers (not illustrated) may have unclear or may lack boundaries therebetween.

The rear redistribution layers 152 may be disposed on or in the rear insulating layer 151, and may redistribute the interconnection structure 130. The rear redistribution layer 152, which is disposed on the rear insulating layer 151, may be referred to as the rear pads 154. The rear redistribution layers 152 and the rear pad 154 may include, for example, a metal material including copper (Cu), aluminum (Al), silver (Ag), tin (Sn), gold (Au), nickel (Ni), lead (Pb), titanium (Ti), or alloys thereof. The rear redistribution layer 152 may include more or fewer redistribution layers than those illustrated in the drawings. The rear pads 154 may be physically and electrically connected to an external device. A barrier layer (not illustrated) may be disposed on a surface of the rear redistribution layers 152 on the rear insulating layer 151.

The rear redistribution vias 153 may pass through or extend into the rear insulating layer 151 to be electrically connected to the rear redistribution layers 152. For example, the rear redistribution vias 153 may interconnect the rear redistribution layers 152 on different levels, and may interconnect the rear redistribution layers 152 that are adjacent to an upper surface of the rear insulating layer 151 and the rear pads 154. The rear redistribution via 153 may be a filled via in which a via hole is filled with or includes a metal material or a conformal via in which a metal material extends along an inner wall of a via hole.

The external connection bumps 160 may be disposed below the front redistribution structure 110. The external connection bumps 160 may be electrically connected to the semiconductor chip 120 and the interconnection structure 130 through the front redistribution layers 112. The semiconductor package 10 may be connected to an external device such as a module substrate, a system board, or the like through the external connection bumps 160. For example, the external connection bumps 160 may include a low melting point metal, for example, tin (Sn) or an alloy including tin (Sn) (Sn—Ag—Cu). In some example embodiments, the external connection bumps 160 may be in the form of a combination of a pillar (or underbump metal) and a ball. The pillar may include copper (Cu) or an alloy of copper (Cu), and the ball may include a solder ball. In some example embodiments, the front insulating layer 111 may include a resist layer that protects or inhibits the external connection bumps 160 from external physical and chemical damage.

The heat dissipation structure 200 may be disposed on at least one side of the upper package 300 and on the rear insulating layer 151 of the lower package 100. The heat dissipation structure 200 may control warpage of the semiconductor package 10, and may externally dissipate heat generated from the lower package 100. The heat dissipation structure 200 may include a dam structure 210, a bonding layer 220, and a heat slug 230.

The dam structure 210 may be disposed to be spaced apart from the rear pads 154 and is on the rear redistribution structure 150. The dam structure 210 may be disposed to be spaced apart from the upper package 300 in a horizontal direction (for example, an X-direction) that is parallel to an upper surface of the rear insulating layer 151. An upper surface of the dam structure 210 may be positioned on a level that is higher than levels of upper surfaces of the rear pads 154 (e.g., a distance between the upper surface of the dam structure 210 and a surface of the front redistribution structure 110 in the Z-direction is greater than respective distances between the upper surfaces of the rear pads 154 and the surface of the front redistribution structure 110 in the Z-direction). The dam structure 210 may at least partially surround a portion of the bonding layer 220, may include a through-hole 210H exposing the upper surface of the rear insulating layer 151, and the through-hole 210H may be partially or completely filled with or include the bonding layer 220. The through-hole 210H may include a closed curve, and may have a ring shape. In some example embodiments, the through-hole 210H may have a shape corresponding to that of the upper surface of the rear insulating layer 151 of the lower package 100. For example, when the upper surface of the rear insulating layer 151 has a rectangular shape, the through-hole 210H may have a rectangular shape. However, the present disclosure is not limited thereto. The dam structure 210 may be spaced apart from the upper package 300 in a first horizontal direction (for example, an X-direction). In this case, a width D1 of the dam structure 210 in the first horizontal direction may be less than a width D2 of the dam structure 210 in a second horizontal direction (for example, a Y-direction), intersecting the first horizontal direction. That is, a distance D1 by which an external surface 210S of the dam structure 210 is spaced apart in the first horizontal direction may be less than a distance D2 by which the external surface 210S of the dam structure 210 is spaced apart in the second horizontal direction. The dam structure 210 may include, for example, a metal material including copper (Cu), aluminum (Al), silver (Ag), tin (Sn), gold (Au), nickel (Ni), lead (Pb), titanium (Ti), or alloys thereof. In some example embodiments, the dam structure 210 may include a conductive material the same as that of the rear pad 154. In some example embodiments, the dam structure 210 may include an insulating material such as an insulating resin, and the insulating resin may include a thermosetting resin such as an epoxy resin, a thermoplastic resin such as polyimide, or a resin in which the above-described resins are impregnated with an inorganic filler. In some example embodiments, the dam structure 210 may include a polymer.

The bonding layer 220 may fill or be in the through-hole 210H of the dam structure 210 that is on the rear insulating layer 151, and may cover or at least partially overlap at least a portion of an internal surface and an upper surface of the dam structure 210. The bonding layer 220 may be referred to as a thermal interface material (TIM). The bonding layer 220 may include a first portion 221 at least partially surrounded by the dam structure 210 in plan view, and a second portion 222 positioned at a level that is higher than that of an upper surface of the dam structure 210 (e.g., a distance between the upper surface of the dam structure 210 and a surface of the front redistribution structure 110 in the Z-direction is less than a distance between a surface of the second portion 222 and the surface of the front redistribution structure 110 in the Z-direction). The first portion 221 of the bonding layer 220 may be defined as a portion that is in or partially or completely fills the through-hole 210H of the dam structure 210. In some embodiments, the first portion 221 may be defined as a portion of the bonding layer 220 positioned at a level that is lower than that of the upper surface of the dam structure 210, and the second portion 222 may be defined as a portion of the bonding layer 220 positioned at a level that is the same as or higher than that of the upper surface of the dam structure 210. The first portion 221 may be in contact with at least a portion of the internal surface of the dam structure 210. In a direction (for example, a Z-direction) perpendicular to the upper surface of the rear insulating layer 151, a thickness H1 of the first portion 221 may be defined as a thickness H1 of the dam structure 210. The second portion 222 may be in contact with at least a portion of the upper surface of the dam structure 210, and may be in contact with at least a portion of a lower surface of the heat slug 230. The second portion 222 may include an external end 222E that extends or protrudes in a horizontal direction. In the direction (for example, the Z-direction) perpendicular to the upper surface of the rear insulating layer 151, a thickness H2 of the second portion 222 may be less than the thickness H1 of the first portion 221. That is, the thickness H2 of the second portion 222 may be less than the thickness H1 of the dam structure 210. The bonding layer 220 may include, for example, a thermally conductive adhesive tape, thermally conductive grease, a thermally conductive adhesive, or the like.

The heat slug 230 may be disposed on the bonding layer 220. The heat slug 230 may be in contact with the second portion 222 of the bonding layer 220, and may be spaced apart from the dam structure 210. An upper surface of the heat slug 230 may be positioned at a level that is lower than an upper surface of an upper encapsulant 340 of the upper package 300, but the present disclosure is not limited thereto (e.g., a distance between the upper surface of the heat slug 230 and a surface of the front redistribution structure 110 in the Z-direction is less than a distance between an upper surface of the upper encapsulant 340 and the surface of the front redistribution structure 110 in the Z-direction). In some example embodiments, the upper surface of the heat slug 230 may be positioned at a level that is substantially the same as that of the upper surface of the upper encapsulant 340. A side surface 230S of the heat slug 230 may be coplanar with the external surface 210S of the dam structure 210, but the present disclosure is not limited thereto. The heat slug 230 may include a material having relatively higher thermal conductivity, such as aluminum (Al), gold (Au), silver (Ag), copper (Cu), iron (Fe), graphite, graphene, or the like.

The heat dissipation structure 200 according to the present disclosure may include the dam structure 210 at least partially surrounding the bonding layer 220, such that the bonding layer 220 is controlled so as not to be underfilled or overfilled, thereby optimizing a contact area between the bonding layer 220 and the heat slug 230 and preventing the bonding layer 220 from invading or being provided in a region in which the upper package 300 is disposed. Accordingly, a semiconductor package having improved heat dissipation properties and improved reliability may be provided.

The upper package 300 may be disposed to be spaced apart from the heat dissipation structure 200, on the lower package 100. The upper package 300 may include an upper package substrate 311, an upper semiconductor chip 320, and an upper encapsulant 340. A lower surface and an upper surface of the upper package substrate 311 may respectively include a lower pad 312 and an upper pad 313 that may be electrically connected to the outside. In addition, the upper package substrate 311 may be a redistribution substrate including a redistribution circuit 314 electrically connecting the lower pad 312 and the upper pad 213 to each other, but the present disclosure is not limited thereto.

The upper semiconductor chip 320 may be mounted on the upper package substrate 311 in a wire bonding manner or a flip-chip bonding manner. The upper semiconductor chip 320 may be referred to as a second semiconductor chip 320, and the semiconductor chip 120 of the lower package 100 may be referred to as a first semiconductor chip 120 or a lower semiconductor chip 120. The upper semiconductor chip 320 may include a plurality of semiconductor chips 322 that are vertically stacked. For example, a plurality of upper semiconductor chips 322 may be stacked on the upper package substrate 310 in a vertical direction and electrically connected to the upper pad 313 of the upper package substrate 311 by a bonding wire WB. The upper semiconductor chip 320 may include a chip bonding film 321 disposed between the plurality of semiconductor chips 322 or between a lowermost semiconductor chip 322 and the upper package substrate 311. In an example, the upper semiconductor chip 320 may include a memory chip, and the lower semiconductor chip 120 may include an AP chip. The upper package substrate 311 may be a substrate on which the upper semiconductor chip 320 is mounted.

Although schematically illustrated in FIG. 1A, the upper package substrate 311, the lower pad 312, the upper pad 313, and the redistribution circuit 314 may have features the same as or similar to those of the front redistribution structure 110. For example, the upper package substrate 311 may include a ground (GND) pattern, a power (PWR) pattern, and a signal(S) pattern. Here, the signal(S) pattern may be defined as a transmission path for various signals, such as a data signal and the like, excluding the ground (GND) pattern, the power (PWR) pattern, and the like.

The upper encapsulant 340 may cover or at least partially overlap at least a portion of the upper semiconductor chip 320 that is on the upper package substrate 311, and may have features the same as or similar to those of the encapsulant 140.

The connection conductors 360 may be disposed below the upper package substrate 311. The connection conductors 360 may be connected to the rear pads 154 on the rear insulating layer 151, and may be electrically connected to the rear redistribution layers 152. For example, the connection conductors 360 may include a low melting point metal, for example, tin (Sn) or an alloy including tin (Sn) (Sn—Ag—Cu). In some example embodiments, the connection conductors 360 may be in the form of a combination of a pillar (or underbump metal) and a ball. The pillar may include copper (Cu) or an alloy of copper (Cu), and the ball may include a solder ball.

The upper underfill layer 365 may at least partially surround the connection conductors 360 that are on the rear insulating layer 151. The upper underfill layer 365 may be in contact with a lower surface of the upper package substrate 311. The upper underfill layer 365 may be spaced apart from the dam structure 210, but the present disclosure is not limited thereto. In an example embodiment, the upper underfill layer 365 may be in contact with the external surface 210S of the dam structure 210. However, even in this case, the upper underfill layer 365 may be spaced apart from the bonding layer 220. FIG. 1A illustrates that the upper underfill layer 365 is positioned between the upper package substrate 311 and the rear insulating layer 151, but the present disclosure is not limited thereto. For example, the upper underfill layer 365 may at least partially surround a portion of a side surface of the upper package substrate 311 in addition to the connection conductors 360. The upper underfill layer 365 may include an insulating resin such as an epoxy resin, and may physically and electrically protect the connection conductors 360. The upper underfill layer 365 may have a capillary underfill (CUF) structure, but the present disclosure is not limited thereto. In some example embodiments, the upper underfill layer 365 may not be present.

Hereinafter, a description overlapping the description provided with reference to FIGS. 1A to 1D will be omitted. In addition, a repeated description in each example embodiment will be omitted.

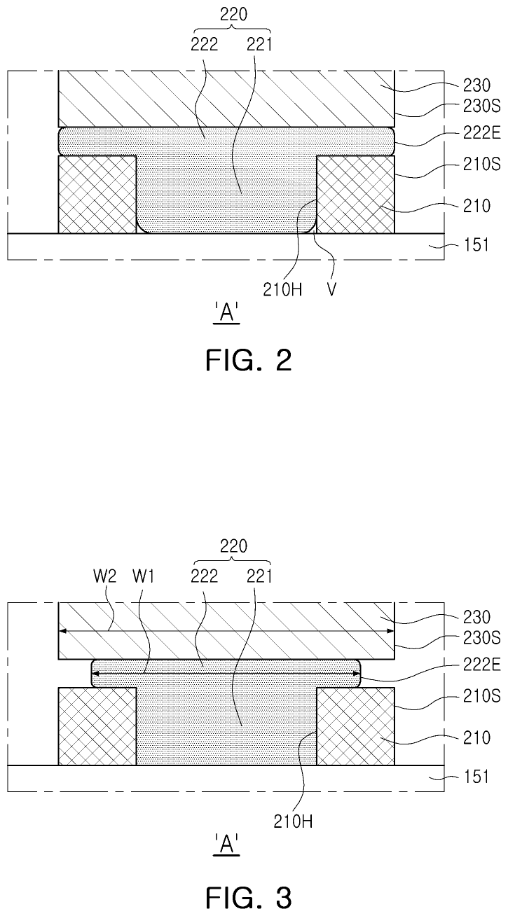

FIGS. 2 to 5 are enlarged views of modifications of region “A” of FIG. 1A.

Referring to FIG. 2 together with FIG. 1A, a void V may be present in the through-hole 210H of the dam structure 210. The void V may be an air space of the through-hole 210H in which the dam structure 210 is not filled. A plurality of voids V may be present, and may be formed to be in contact with the dam structure 210 or the rear insulating layer 151, but the present disclosure is not limited thereto. Even when the void V is present in the through-hole 210H, partially or completely filling of the bonding layer 220 may be controlled by the dam structure 210, thereby optimizing a contact area between the bonding layer 220 and the heat slug 230.

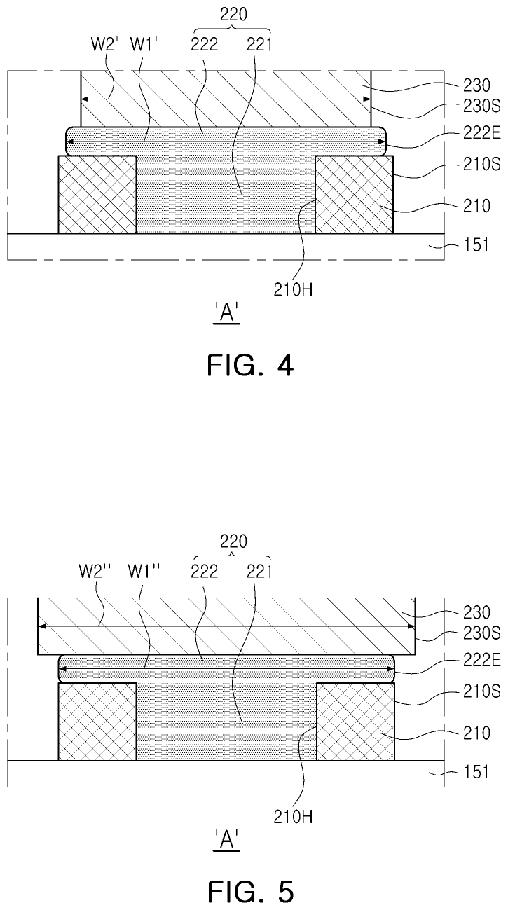

Referring to FIG. 3 together with FIG. 1A, an external end 222E of the second portion 222 of the bonding layer 220 may be positioned further inwardly than the external surface 210S of the dam structure 210 and a side surface 230S of the heat slug 230. A width W1 of the second portion 222 in a horizontal direction, or a distance W1 between external ends 222E of the second portion 222 in the horizontal direction may be less than a width W2 of the heat slug 230 in the horizontal direction. The widths in the horizontal direction in FIG. 3 may represent widths in a first horizontal direction (for example, an X-direction). However, even in a second horizontal direction (for example, a Y-direction) intersecting the first horizontal direction, the external end 222E of the second portion 222 of the bonding layer 220 may also be positioned further inwardly than the external surface 210S of the dam structure 210 and the side surface 230S of the heat slug 230. Hereinafter, in the description provided with reference to FIGS. 4 and 5, a description overlapping the description provided with reference to FIG. 3 will be omitted.

Referring to FIG. 4 together with FIG. 1A, the side surface 230S of the heat slug 230 may be positioned further inwardly than the external end 222E of the second portion 222 of the bonding layer 220, and the external end 222E may be positioned further inwardly than the external surface 210S of the dam structure 210. A width W1′ of the second portion 222 in the horizontal direction may be greater than a width W2′ of the heat slug 230 in the horizontal direction.

Referring to FIG. 5 together with FIG. 1A, the side surface 230S of the heat slug 230 may be positioned further outwardly than the external end 222E of the second portion 222. A width W1″ of the second portion 222 in the horizontal direction may be less than a width W2″ of the heat slug 230 in the horizontal direction.

The example embodiments of FIGS. 2 to 5 illustrate an arrangement relationship of the dam structure 210, the bonding layer 220, and the heat slug 230, and shapes of the dam structure 210, the bonding layer 220, and the heat slug 230 and the arrangement relationship between the dam structure 210, the bonding layer 220, and the heat slug 230 are not limited to the example embodiments of FIGS. 2 to 5. The forms of the examples embodiment may be combined with each other within a compatible range. For example, the side surface 230S of the heat slug 230 may be positioned further outwardly than the external end 222E of the second portion 222 of the bonding layer 220, and may be positioned further inwardly than the external surface 210S of the dam structure 210.

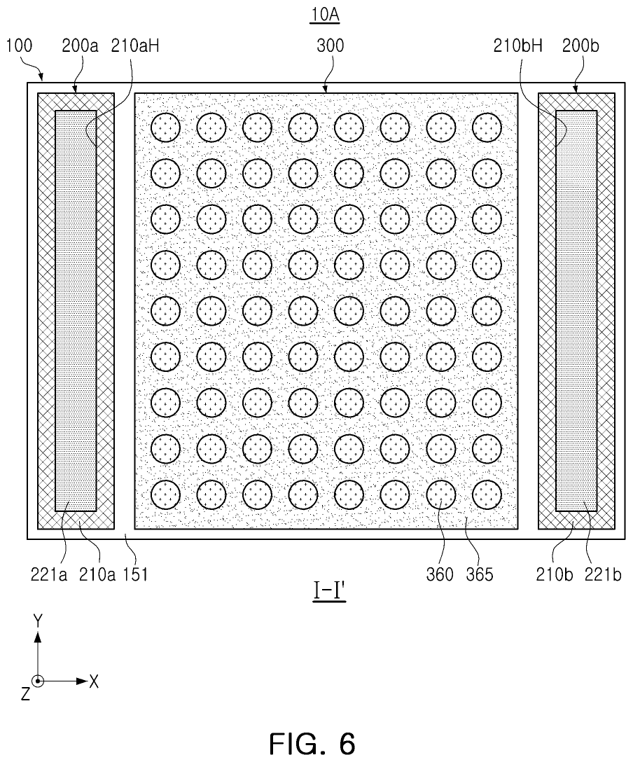

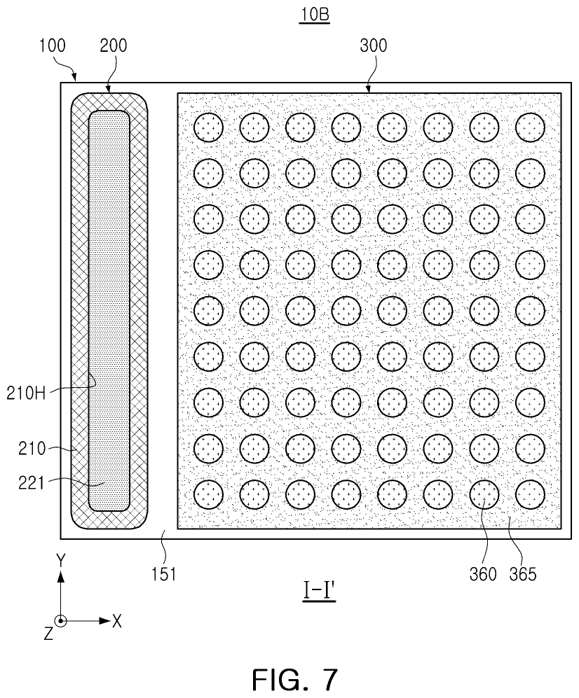

FIGS. 6 and 7 are cross-sectional views of semiconductor packages according to example embodiments. FIGS. 6 and 7 schematically illustrate a cross-section corresponding to a cross-section taken along line I-I′ of FIG. 1A.

Referring to FIG. 6, a plurality of heat dissipation structures 200 of a semiconductor package 10A may be present, a first heat dissipation structure 200a may be disposed to be adjacent to one side surface of an upper package 300 and may be on a rear insulating layer 151 of a lower package 100, and a second heat dissipation structure 200b may be disposed to be adjacent to the other side surface opposing the one side surface of the upper package 300 opposing the first heat dissipation structure 200a. The number and shapes of the heat dissipation structures 200 may be changed in various manners. For example, the heat dissipation structures 200 may be disposed to opposite all four side surfaces of the upper package 300 that is on the lower package 100. The heat dissipation structure 200 may have a bar shape extending in a direction, but the present disclosure is not limited thereto. For example, the heat dissipation structure 200 may have a ring shape at least partially surrounding a side surface of the upper package 300 that is on the lower package 100. The first heat dissipation structure 200a may include a dam structure 210a, a through-hole 210aH, a bonding layer (not denoted in FIG. 6) that includes a first portion 221a and a second portion 222a (not denoted in FIG. 6), and a heat slug (not denoted in FIG. 6). The second heat dissipation structure 200b may include a dam structure 210b, a through-hole (not denoted in FIG. 6), a bonding layer (not denoted in FIG. 6) that includes a first portion 221b and a second portion 222b (not denoted in FIG. 6), and a heat slug (not denoted in FIG. 6).

Referring to FIG. 7, and unlike the semiconductor package 10A of FIG. 6, a dam structure 210 of a semiconductor package 10B may not have an edge at which external surfaces thereof intersect, and a corresponding portion may be a curved surface. In some example embodiments, in plan view, a through-hole 210H may have a rectangular shape in addition to an elliptical shape. Planar shapes of the dam structure 210 and the through-hole 210H are not limited thereto. For example, the planar shapes of the dam structure 210 and the through-hole 210H may be various polygonal shapes, such as a hexagonal shape, an octagonal shape, and the like. Depending on the shapes of the dam structure 210 and the through-hole 210H, a shape of a first portion 221 disposed in the through-hole 210H may be modified in various manners.

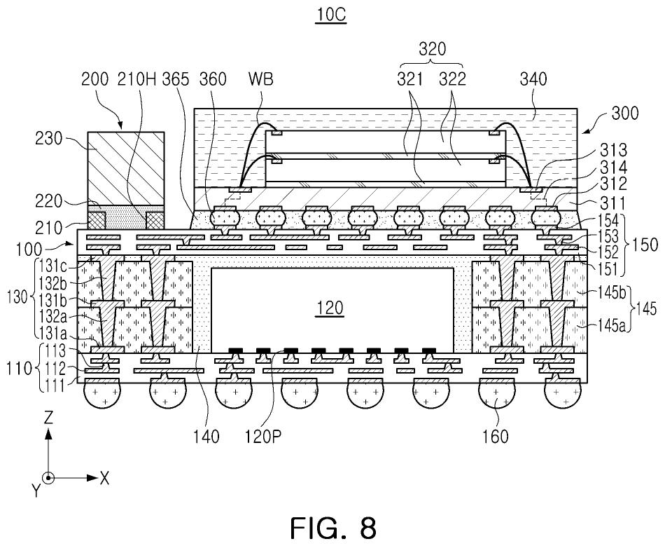

FIG. 8 is a cross-sectional view of a semiconductor package according to example embodiments.

Referring to FIG. 8, in a semiconductor package 10C, an interconnection structure 130 may be disposed around a semiconductor chip 120, and may include first to third intermediate wiring layers 131a, 131b, and 131c and first and second intermediate wiring vias 132a and 132b. The semiconductor package 10C may further include an intermediate insulating layer 145 that at least partially overlaps or covers at least a portion of the interconnection structure 130.

The intermediate insulating layer 145 may at least partially surround at least a portion of the interconnection structure 130, and an encapsulant 140 may at least partially overlap or cover at least a portion of each of the interconnection structure 130 and the intermediate insulating layer 145. The intermediate insulating layer 145 may include a first intermediate insulating layer 145a disposed on an upper surface of a front redistribution structure 110, and a second intermediate insulating layer 145b disposed on an upper surface of the first intermediate insulating layer 145a. The first intermediate wiring layer 131a may be buried in a lower surface of the first intermediate insulating layer 145a, the second intermediate wiring layer 131b may be disposed on the upper surface of the first intermediate insulating layer 145a, and the third intermediate wiring layer 131c may be disposed on an upper surface of the second intermediate insulating layer 145b. The first intermediate wiring via 132a may pass through or extend into the first intermediate insulating layer 145a to connect the first and second intermediate wiring layers 131a and 131b to each other, and the second intermediate wiring via 132b may pass through or extend into the second intermediate insulating layer 145b to connect the second and third intermediate wiring layers 131b and 131c to each other.

The encapsulant 140 may at least partially overlap or cover at least a portion of the intermediate insulating layer 135, and an upper surface of the encapsulant 140 and an upper surface of the third intermediate wiring layer 131c may be substantially coplanar with each other. Other features of the semiconductor package 10C that are not specifically described herein may be the same as or similar to those of the semiconductor package 10 described with reference to FIG. 1A.

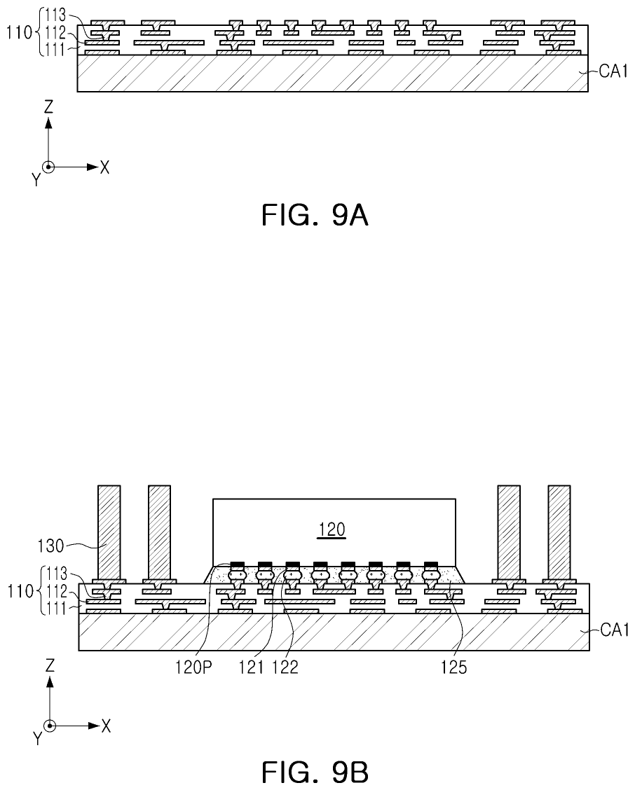

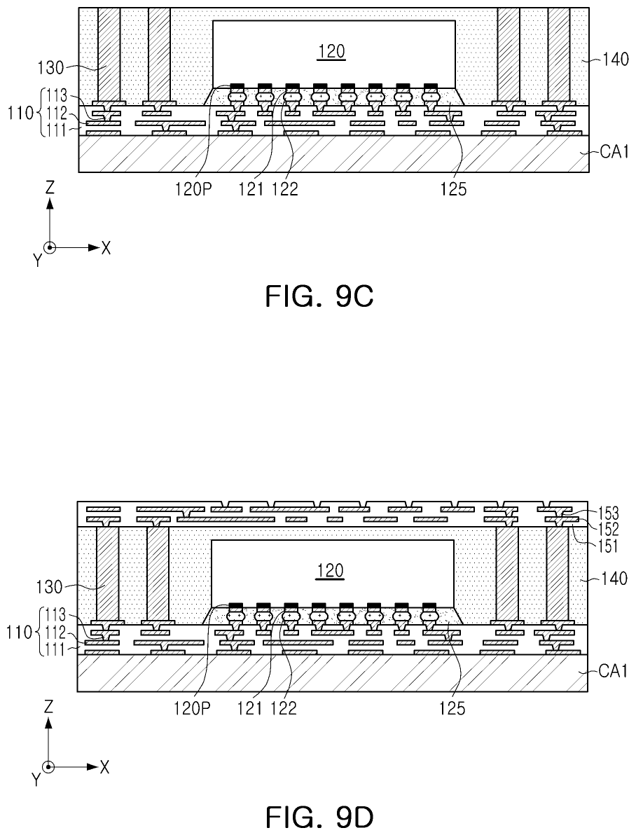

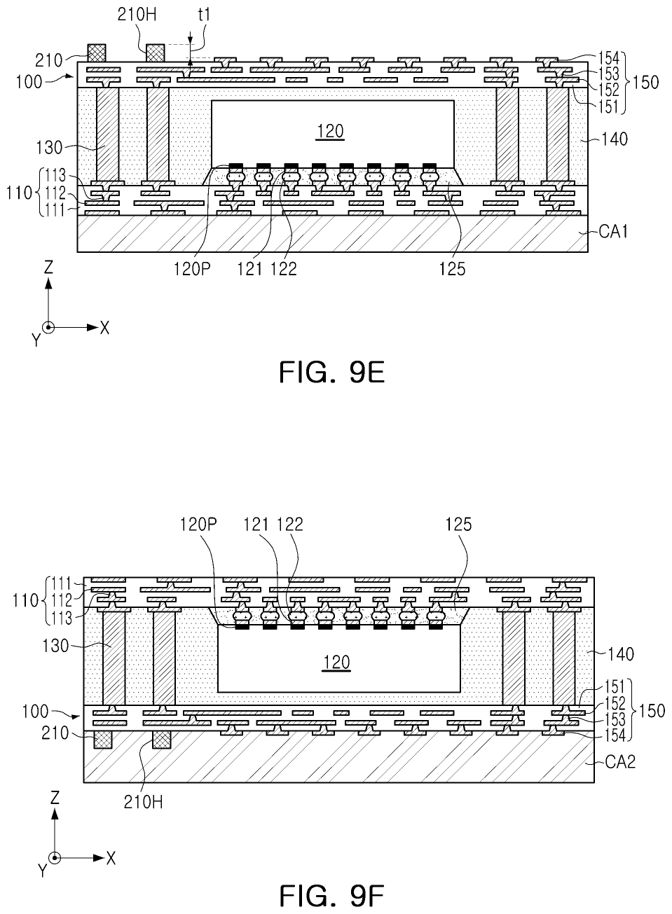

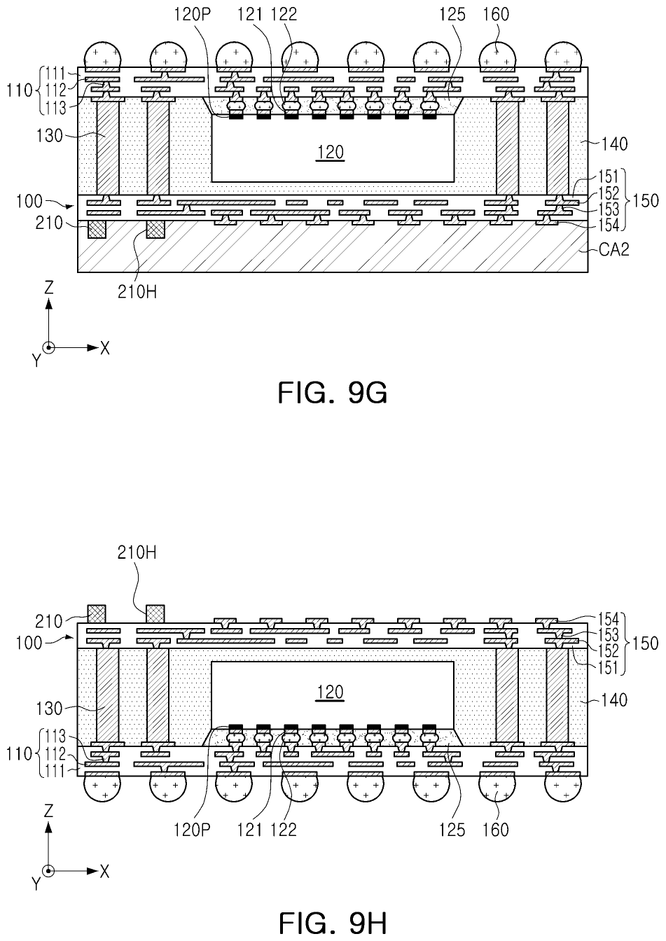

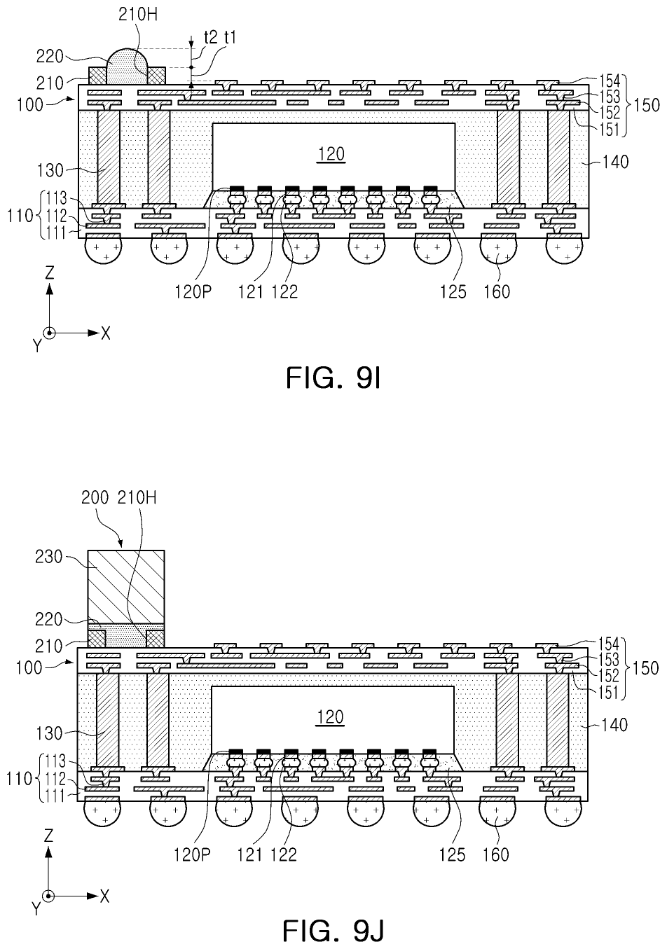

FIGS. 9A to 9J are diagrams of sequential processes of a method of manufacturing a semiconductor package according to example embodiments. FIGS. 9A to 9J illustrate a method of manufacturing the semiconductor package 10 illustrated in FIG. 1A.

Referring to FIG. 9A, a front redistribution structure 110 may be formed on a first carrier CA1. For example, the first carrier CA1 may have a copper clad laminate (CCL) sequentially coated with a polymer layer including a curable resin, and a metal layer including nickel (Ni), titanium (Ti), and the like. The front redistribution structure 110 may include a front insulating layer 111, front redistribution layers 112, and front redistribution vias 113. The front insulating layer 111 may be formed by sequentially coating and curing a photosensitive material, for example, a PID. The front redistribution layers 112 and the front redistribution vias 113 may be formed by performing an exposure process and a development process to form a via hole passing through or extending into the front insulating layer 111, and patterning a metal material on the front insulating layer 111 using a plating process. The front redistribution layers 112 may also be formed on an upper surface of the front redistribution structure 110, and a barrier layer (not illustrated) including nickel (Ni), gold (Au), and the like may be formed.

Referring to FIG. 9B, an interconnection structure 130 may be formed on the front redistribution layers 112, and a semiconductor chip 120 may be mounted on the front redistribution structure 110. The interconnection structure 130 may be formed by performing a plating process. The interconnection structure 130 may include a metal material such as copper (Cu). In some example embodiments, a metal seed layer (not illustrated), including titanium (Ti), copper (Cu), and the like, may be formed on a lower surface of the interconnection structure 130. The semiconductor chip 120 may be mounted in a flip-chip manner. For example, the semiconductor chip 120 may be connected to the front redistribution layers 112 through a connection pillar 121 and a connection solder 122 formed on a connection terminal 120P. An underfill layer 125 may be formed between the semiconductor chip 120 and the front redistribution structure 110. The underfill layer 125 may be formed using a CUF process, but the present disclosure is not limited thereto.

Referring to FIG. 9C, an encapsulant 140 may be formed to encapsulate at least a portion of each of the semiconductor chip 120 and the interconnection structure 130. The encapsulant 140 may be formed, for example, by coating and curing an EMC. An upper surface of the encapsulant 140 may be formed at a level that is higher than that of an upper surface of the interconnection structure 130. Thereafter, a portion of the interconnection structure 130 and the encapsulant 140 may be etched using a planarization process, thereby exposing the upper surface of the interconnection structure 130 to the upper surface of the encapsulant 140. Accordingly, as illustrated, the upper surface of the interconnection structure 130 and the upper surface of the encapsulant 140 may be coplanar with each other. In some example embodiments, an upper surface of the semiconductor chip 120 may be exposed during the planarization process.

Referring to FIG. 9D, a rear redistribution structure 150 covering or overlapping the upper surface of the encapsulant 140, the upper surface of the semiconductor chip 120, and the upper surface of the interconnection structure 130 may be formed. The rear redistribution structure 150 may be formed using a similar process to that of the front redistribution structure 110. The rear insulating layer 151 may be formed by sequentially coating and curing a photosensitive material, for example, a PID. The rear redistribution layers 152 and the rear redistribution vias 153 may be formed by performing an exposure process and a development process to form a via hole passing through or extending into the rear insulating layer 151, and patterning a metal material on the rear insulating layer 151 using a plating process.

Referring to FIG. 9E, a dam structure 210 and rear pads 154 may be formed on the rear insulating layer 151. The dam structure 210 may be formed to be spaced apart from the rear pads 154 in plan view, and may be formed to include a through-hole 210H. An upper surface of the dam structure 210 may be formed at a level that is higher than levels of upper surfaces of the rear pads 154. That is, in a direction, perpendicular to an upper surface of the rear insulating layer 151, a thickness of the dam structure 210 may be greater than a thickness of each of the rear pads 154. Accordingly, a thickness difference t1 between the dam structure 210 and the rear pads 154 may occur. The dam structure 210 may be formed simultaneously with the rear pads 154 or may be formed using a separate process from that of the rear pads, depending on a material included therein. For example, when the dam structure 210 includes a conductive material the same as that of the rear pads 154, the dam structure 210 may be formed simultaneously using the same process as that of the rear pads 154. Conversely, when the dam structure 210 includes a conductive material different from that of the rear pads 154 or an insulating material, the dam structure 210 may be formed using a separate process after or before the rear pads 154 are formed.

Referring to FIG. 9F, a second carrier CA2 may be formed on the rear redistribution structure 150, and the package may be inverted to be subject to a subsequent process. For ease of description, FIGS. 9F and 9G illustrate that the semiconductor package is rotated or inverted in the form of a mirror image. A portion of the second carrier CA2 in contact with the rear redistribution structure 150 may include a bonding material, and the rear pads 154 and the dam structure 210 may be buried in the bonding material of the second carrier CA2. The first carrier CA1 may be removed to expose an upper surface of the front redistribution structure 110 (based on FIG. 9F) and to expose one surfaces of uppermost front redistribution layers 112 (based on FIG. 9F).

Referring to FIGS. 9G and 9H, external connection bumps 160 in contact with the exposed front redistribution layers 112 may be formed. After the external connection bumps 160 are formed, the package may be inverted again to be subject to a subsequent process. For the subsequent process, the second carrier CA2 may be removed.

Referring to FIG. 9I, a bonding layer 220 that partially or completely fills or is in the through-hole 210H of the dam structure 210 may be formed on the rear insulating layer 151. An upper end of the bonding layer 220 may be formed at a level that is higher than that of the upper surface of the dam structure 210, and accordingly a level difference t2 between the upper end of the bonding layer 220 and the upper surface of the dam structure 210 may occur.

Referring to FIG. 9J, a heat dissipation structure 200 may be formed by disposing a heat slug 230 on the bonding layer 220. Referring to FIGS. 1C and 9J together, the heat slug 230 may be disposed, and accordingly the bonding layer 220 may be compressed to form a second portion 222 covering or at least partially overlapping the upper surface of the dam structure 210 and having an external end 222E. Depending on an amount of the bonding layer 220 and an arrangement method of the heat slug 230, arrangements of the dam structure 210, the bonding layer 220, and the heat slug 230 may be modified in various manners, as illustrated in the example examples illustrated in FIGS. 1C and 2 to 5. Thereafter, referring to FIGS. 1A and 9J together, an upper package 300, spaced apart from the heat dissipation structure 200 and connected to the rear pads 154, may be disposed on the rear redistribution structure 150. The upper package 300 may be electrically connected to the rear redistribution layers 152 including the rear pads 154 through connection conductors 260.

According to example embodiments of the present disclosure, a heat dissipation structure including a dam structure may be applied such that a semiconductor package may have improved reliability.

While example embodiments have been shown and described above, it will be apparent to those skilled in the art that modifications and variations could be made without departing from the scope of the present disclosure as defined by the appended claims.

What is claimed is:

1. A semiconductor package comprising:
a front redistribution structure that comprises a front insulating layer and front redistribution layers in the front insulating layer;
a semiconductor chip on a first surface of the front redistribution structure;
external connection bumps on a second surface of the front redistribution structure, wherein the external connection bumps are electrically connected to ones of the front redistribution layers;
an encapsulant on a portion of the semiconductor chip and on the first surface of the front redistribution structure;
a rear redistribution structure that comprises a rear insulating layer on the encapsulant, rear redistribution layers in the rear insulating layer, and rear pads on the rear insulating layer;
an interconnection structure that extends into the encapsulant and electrically connects the front redistribution layers and the rear redistribution layers to each other;
an upper package that is on the rear redistribution structure and is electrically connected to the rear pads of the rear redistribution structure; and
a heat dissipation structure that comprises a bonding layer that is on at least one side of the upper package and on the rear redistribution structure,
wherein the heat dissipation structure comprises a dam structure that at least partially surrounds at least a portion of the bonding layer in plan view and is on the rear redistribution structure, and
wherein the heat dissipation structure comprises a heat slug on the bonding layer.

2. The semiconductor package of claim 1, wherein:
the bonding layer comprises a first portion that is at least partially surrounded by the dam structure in plan view and a second portion,
the second portion is separated from the first surface of the front redistribution structure by a first distance in a first direction that is perpendicular to the first surface of the front redistribution structure,
an upper surface of the dam structure is separated from the first surface of the front redistribution structure by a second distance in the first direction, and
the second distance is less than the first distance.

3. The semiconductor package of claim 2, wherein the first portion of the bonding layer contacts at least a portion of a side surface of the dam structure.

4. The semiconductor package of claim 2, wherein the second portion of the bonding layer contacts at least a portion of the upper surface of the dam structure.

5. The semiconductor package of claim 2, wherein in the first direction, a thickness of the first portion is greater than a thickness of the second portion.

6. The semiconductor package of claim 1, wherein the heat slug is spaced apart from the dam structure in a first direction that is perpendicular to the first surface of the front redistribution structure.

7. The semiconductor package of claim 1, wherein:
an upper surface of the dam structure is separated from the first surface of the front redistribution structure by a first distance in a first direction that is perpendicular to the first surface of the front redistribution structure,
upper surfaces of the rear pads are separated from the first surface of the front redistribution structure by a second distance in the first direction, and
the first distance is greater than the second distance.

8. The semiconductor package of claim 1, wherein the dam structure and the rear pads include a same conductive material.

9. The semiconductor package of claim 1, wherein the bonding layer contacts a lower surface of the heat slug.

10. The semiconductor package of claim 1, wherein the upper package comprises an upper package substrate, an upper semiconductor chip on the upper package substrate, an upper encapsulant on at least a portion of the upper semiconductor chip, and connection conductors that are electrically connected to the rear pads.

11. The semiconductor package of claim 10, wherein:
an upper surface of the dam structure is separated from the first surface of the front redistribution structure by a first distance in a first direction that is perpendicular to the first surface of the front redistribution structure,
a lower surface of the upper package substrate is separated from the first surface of the front redistribution structure by a second distance in the first direction, and
the first distance is less than the second distance.

12. The semiconductor package of claim 10, wherein:
an upper surface of the heat slug is separated from the first surface of the front redistribution structure by a first distance in a first direction that is perpendicular to the first surface of the front redistribution structure
an upper surface of the upper encapsulant is separated from the first surface of the front redistribution structure by a second distance in the first direction, and
the first distance is less than the second distance.

13. A semiconductor package comprising:
a lower package and a heat dissipation structure,
wherein the lower package comprises:
a front redistribution structure that comprises front redistribution layers;
a semiconductor chip on the front redistribution structure;
an encapsulant that is on a portion of the semiconductor chip and on the front redistribution structure; and
a rear redistribution structure that comprises a rear insulating layer on the encapsulant, rear redistribution layers in the rear insulating layer, and rear pads on the rear insulating layer, and
wherein the heat dissipation structure comprises:
a dam structure that is spaced apart from the rear pads in a first direction that is parallel to an upper surface of the lower package and is on the rear insulating layer, the dam structure defining a through-hole that exposes a first portion of an upper surface of the rear insulating layer;
a bonding layer that is in at least a portion of the through-hole and is on at least a portion of an upper surface of the dam structure; and
a heat slug on the bonding layer.

14. The semiconductor package of claim 13, wherein the dam structure and the rear pads comprise at least one of aluminum (Al) or gold (Au).

15. The semiconductor package of claim 13, wherein the dam structure comprises a polymer.

16. The semiconductor package of claim 13, wherein an area of the first portion of the upper surface of the rear insulating layer is less than an area of a lower surface of the heat slug.

17. The semiconductor package of claim 13, wherein:
the bonding layer comprises a first portion in the through-hole and a second portion,
the second portion is separated from the upper surface of the lower package by a first distance in a second direction that is perpendicular to the first direction,
the upper surface of the dam structure is separated from the upper surface of the lower package by a second distance in the second direction,
the first distance is greater than the second distance, and
the second portion contacts at least a portion of a lower surface of the heat slug.

18. The semiconductor package of claim 13, wherein the heat slug comprises at least one of aluminum (Al), gold (Au), silver (Ag), copper (Cu), iron (Fe), graphite, or graphene.

19. A semiconductor package comprising:
a lower package and an upper package,
wherein the lower package comprises:
a front redistribution structure that comprises a front insulating layer and front redistribution layers in the front insulating layer;
a semiconductor chip that is on the front redistribution structure and electrically connected to the front redistribution layers;
an encapsulant that is on at least a portion of the semiconductor chip and is on the front redistribution structure; and
a rear redistribution structure that comprises a rear insulating layer on the encapsulant, rear redistribution layers in the rear insulating layer, and rear pads on the rear insulating layer,
wherein the upper package comprises:
an upper package substrate;
an upper semiconductor chip on the upper package substrate;
an upper encapsulant on at least a portion of the upper semiconductor chip; and
connection conductors that are electrically connected to the rear pads,
wherein the semiconductor package comprises a heat dissipation structure that comprises a bonding layer that is spaced apart from the upper package in a first direction that is parallel to an upper surface of the lower package and is on the rear redistribution structure, a dam structure that at least partially surrounds a portion of the bonding layer in plan view and is on the rear redistribution structure, and a heat slug on the bonding layer.

20. The semiconductor package of claim 19, wherein:
the upper package further comprises an underfill layer that at least partially surrounds the connection conductors in plan view and is on the rear redistribution structure, and
the underfill layer is spaced apart from the dam structure in the first direction.
